(19) United States
(12) Patent Application Publication
(10) Pub. No.: US 2017/0133979 A1
(43) Pub. Date: May 11, 2017

(54) PHOTOVOLTAIC APPARATUS AND SYSTEM COMPRISING ROTATABLE SOLAR PANEL AND REFLECTOR

(71) Applicant: SolarWorld AG, Bonn (DE)

(72) Inventors: Frank Asbeck, Bonn (DE); Markus Hund, Euskirchen (DE); Matthias Georgi, Dresden (DE)

(21) Appl. No.: 14/933,087

(22) Filed: Nov. 5, 2015

(51) Int. Cl. H02S 40/22; H01L 31/068; H02S 20/30

(52) U.S. Cl. CPC H02S 40/22; H02S 20/30; H01L 31/0684

(57) ABSTRACT

A photovoltaic apparatus may have a solar panel with at least one bifacial solar cell. The apparatus may include a solar panel, a support structure, a mounting member, and at least one reflector. A first location of the support structure may be configured to rotatably attach to the solar panel. A first location of the mounting membermounting member may be configured to rotatably attach to a first location of the support structure. At least one reflector may be configured to attach to a second location of the mounting member. The reflector(s) may reflect light onto a first side and/or a second side of the solar panel, and the reflector(s) may be fixed relative to the solar panel; the reflector(s) and the solar panel may be configured to rotate together about an axis.

### TECHNICAL FIELD

Various embodiments relate generally to a photovoltaic apparatus having a solar panel, a support structure configured to rotatably attach to the solar panel, a mounting member configured to rotatably attach to the support structure, and at least one reflector configured to attach to the mounting member.

### BACKGROUND

Photovoltaic panels (i.e. solar panels) may convert sunlight into electricity, also known as capturing solar energy for conversion into usable electricity. Of the utmost importance when dealing with solar energy is to capture the largest amount of sunlight as possible.

Thus, it would be beneficial to create solar panels where additional sunlight could be captured by solar cells within a solar panel for converting the sunlight into usable electricity.

### SUMMARY

Various embodiments provide a photovoltaic apparatus. The photovoltaic apparatus may have a solar panel with at least one bifacial solar cell where the solar panel includes a first side and a second side. The apparatus may further include a support structure having a first location and a second location where the first location of the support structure is configured to rotatably attach to the second side of the solar panel. The second location of the support structure may be configured to attach to a ground surface. A mounting member comprising a first location and a second location may be configured to rotatably attach to the first location of the support structure. At least one reflector may attach to the second location of the mounting member where at least one reflector reflects light onto the first side and/or the second side of the solar panel, and the reflector(s) may be fixed relative to the solar panel. Thus, the reflector(s) and the solar panel may be configured to rotate together about an axis.

In another non-limiting embodiment of the photovoltaic apparatus, the solar panel may additionally have a first end and a second end. In addition, the support structure may be configured to rotatably attach to the first end of the solar panel.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1-10 depict a side view of a photovoltaic apparatus in accordance with various embodiments.

### DESCRIPTION

The following detailed description refers to the accompanying drawings that show, by way of illustration, specific details and embodiments in which the invention may be practiced. Any embodiment or design described is not necessarily to be construed as preferred or advantageous over other embodiments or designs.

Various embodiments provide a photovoltaic apparatus having a solar panel, a support structure, a mounting member, and at least one reflector configured to reflect light onto a first side and/or a second side of the solar panel and where the reflector(s) is fixed relative to the solar panel such that the reflector(s) and the solar panel are configured to rotate together about an axis. Furthermore, various embodiments provide for an increase of sunlight directed towards the solar panel. Moreover, in various embodiments, the reflector(s) may preclude the solar panel from contacting a ground surface as the reflector may absorb any force upon contact with a ground surface. Further, the reflector(s) may have more than one section where at least one section may bend or fold about a jointed axis upon contact with a ground surface to preclude damage to the reflector(s). Said differently, the jointed axis may allow at least one section to bend or fold in a different direction from a different section upon contact with the ground surface. In another non-limiting embodiment, the reflector(s) may return to its/their original form after contact with the ground surface.

In another non-limiting embodiment, the reflector(s) may have a material, such as but not limited to a metal; a plastic (e.g. polyethylene, polypropylene, polyvinylchloride, etc.; a rubber; and combinations thereof. In another non-limiting embodiment, the reflector(s) may be reflective by itself (e.g. a reflective metal), or the material of the reflector(s) may have a reflective coating or reflective paint applied thereto. In yet another non-limiting embodiment, the reflector(s) may have a ridged material, a perforated material, a corrugated material, and combinations thereof.

In another non-limiting embodiment, at least one dimension of the reflector(s) may extend beyond at least one dimension of the solar panel. For example, the width of the reflector(s) may be wider or narrower than the solar panel; similarly, the length of the reflector(s) may be longer or shorter than the solar panel. The dimensions of the reflector(s) and/or the solar panel depends on many factors, such as but not limited to cost, a direction of the sun at any given time, and the like. Such embodiment(s) may result in an improved ability of the solar panel (and embodied bifacial solar cell(s)) to capture solar energy.

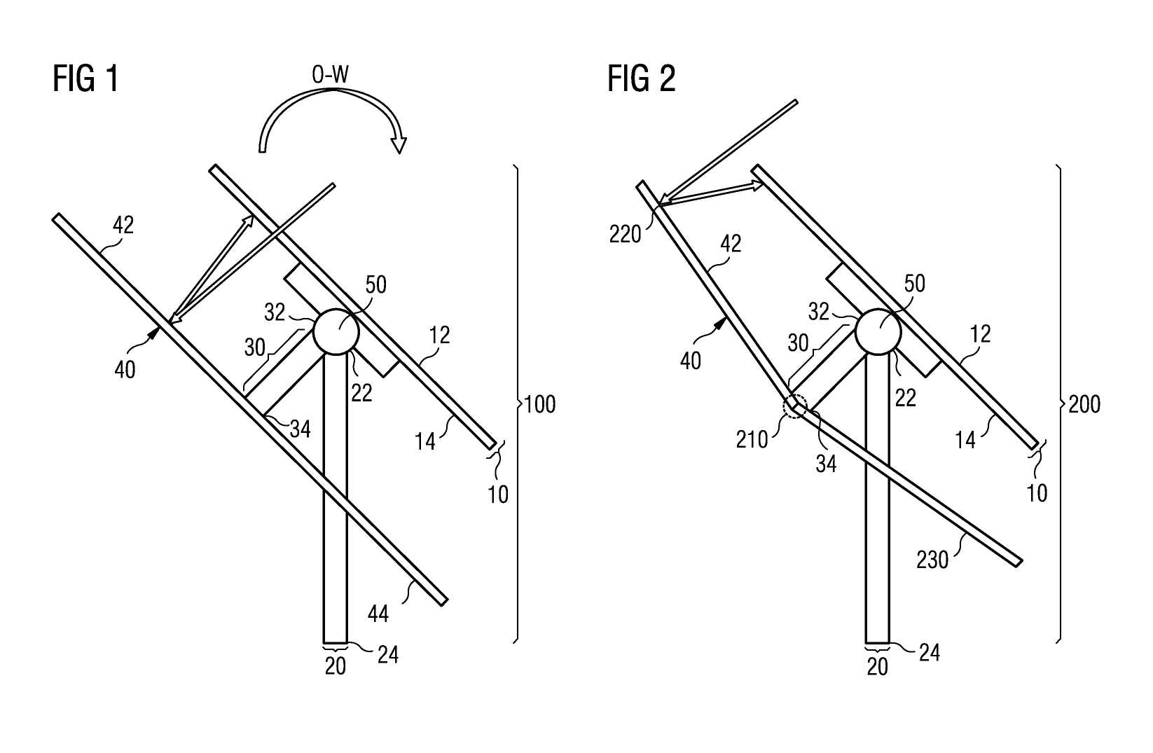

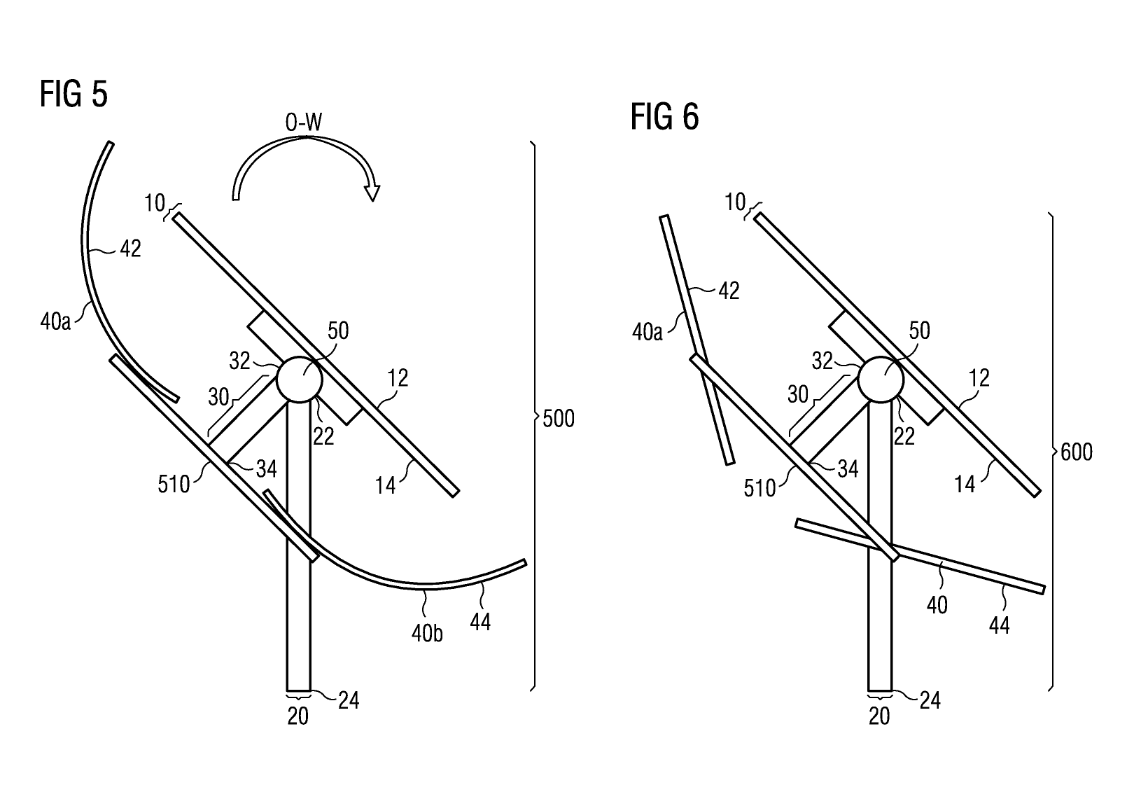

In a non-limiting embodiment, the reflector(s) may have a shape, such as but not limited to a parabolic shape, a curved shape, a flat shape, and combinations thereof. For example, see FIG. 1 for a flat shape, see FIGS. 5, 7-8, and 10 for a parabolic and/or curved shape.

In another non-limiting embodiment, the reflector(s) may have an orientation substantially parallel to the solar panel, or the reflector(s) may have an orientation substantially perpendicular to the solar panel as will be described in conjunction with the FIGs. below. As used herein, the term ‘substantially’ parallel or ‘substantially’ perpendicular refers to reflector(s) within 20 degrees or less that are parallel or perpendicular to the plane of the solar panel, alternatively the reflector(s) may be within 10 degrees or less that are parallel or perpendicular to the plane of the solar panel, or the reflector(s) may be within 5 degrees or less that are parallel or perpendicular to the plane of the solar panel in another non-limiting embodiment.

Now turning to the Figures, FIG. 1 depicts a side view of a photovoltaic apparatus 100 in accordance with various embodiments.

A photovoltaic apparatus 100 may include a solar panel 10 having a first side 12 and a second side 14 where the solar panel 10 includes at least one bifacial cell (not shown). In a non-limiting embodiment, the first side 12 may face the sun. As used herein, a ‘bifacial’ solar cell is a solar cell within the solar panel where the bifacial solar cell has a front side and a back side, and both sides are configured to capture solar energy.

The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 of least one reflector 40. The reflector(s) 40 is/are configured to reflect light (represented by the arrows in the figure) onto the first side 12 and/or the second side 14 of the solar panel 10. In addition, the reflector(s) 40 may be fixed relative to the solar panel 10, such that the reflector(s) 40 and the solar panel 10 are configured to rotate together about an axis 50.

‘Rotatably attach’ as used herein means that two components are attached at a rotatable point, i.e. a first component may rotate at the rotatable point around the second component or vice versa. For example, a rotatable point exists at the point of attachment between the solar panel 10, the mounting member 30, and the support structure 20. Thus, the mounting member 30 and the solar panel 10 may be assembled to rotate about the support structure 20 at the axis 50 in a non-limiting embodiment.

FIG. 2 depicts a side view of a photovoltaic apparatus 200 similar to the apparatus described in FIG. 1; similar numbers refer back to the same elements described in FIG. 1. Here, the reflector 40 may be configured to have at least two sections, such as a first section 220 and a second section 230 in a non-limiting embodiment. The first section 220 may be configured to move in a different direction from at least one other section, such as the second section 230 as depicted. Here, the two sections 220, 230 are depicted to have a moveable point 210 at the location of attachment of the reflector 40 to the mounting member 30. However, a moveable point may exist anywhere on either the first section 220 and/or the second section 230, as well as anywhere on additional sections that may be included in the reflector(s) but not depicted in FIG. 2.

In addition, such movement at or of a moveable point may be or include, but is not limited to, folding, bending, rotating about a jointed axis, and combinations thereof. A ‘section’ as used herein is defined to be any type of division within the reflector, whether the division is visible or not. For example, a reflector may be bendable (or otherwise configured to be moveable) throughout the entire reflector, and each location where the reflector is bendable or moveable represents a division between at least two sections.

The photovoltaic apparatus 200 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 of least one reflector 40. The reflector(s) 40 is/are configured to reflect light (represented by the arrows in the figure) onto the first side 12 and/or the second side 14 of the solar panel 10. The reflector(s) 40 may be fixed relative to the solar panel 10, such that the reflector(s) 40 and the solar panel 10 are configured to rotate together about an axis 50.

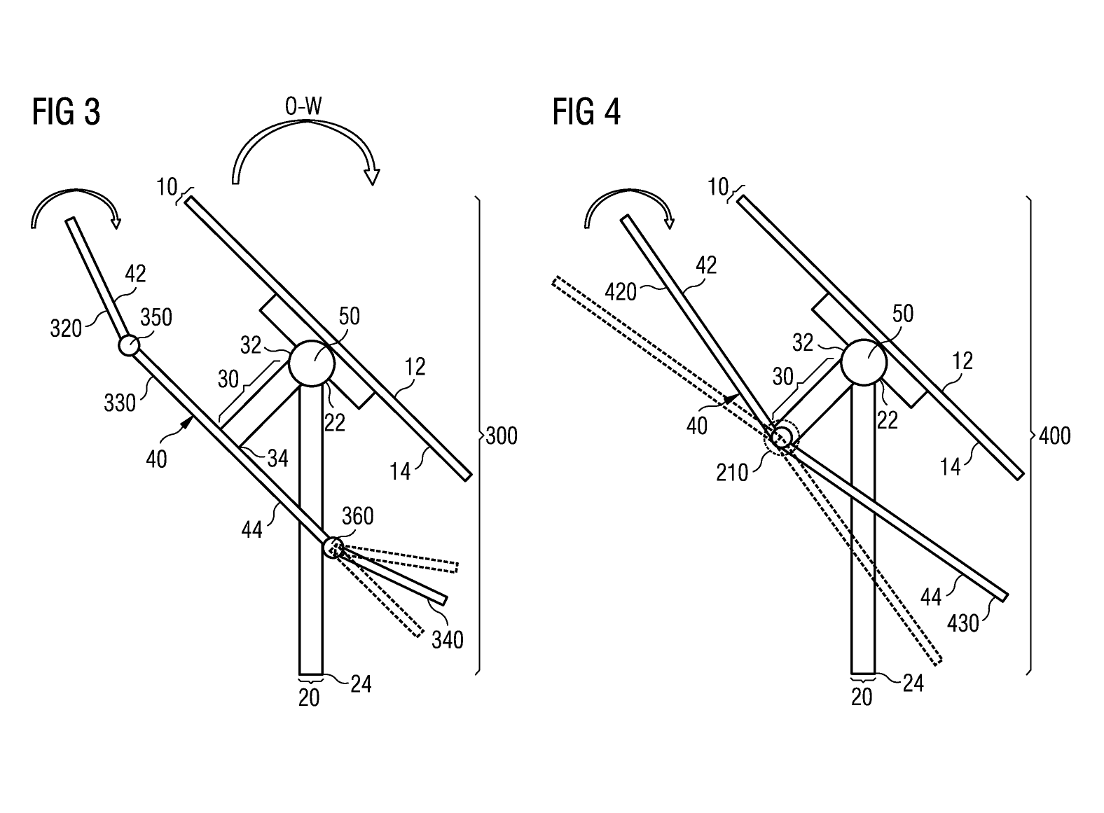

FIG. 3 depicts a side view of a photovoltaic apparatus 300 similar to the apparatuses described in FIG. 1 and FIG. 2; similar numbers refer back to the same elements described therebefore. In addition, any additional features depicted in FIG. 3 may also be incorporated into either FIG. 1 and/or FIG. 2 or incorporated into any combination of the embodiments depicted in FIGS. 1-2.

FIG. 3 depicts a reflector 40 having at least three sections 320, 330, 40 where a first moveable point 350 separates a first section 320 from a second section 330, and where a second moveable point 360 separates the second section 330 from a third section 340. The first section 320 may move about the movable point 350 in either direction relative to the second section 330, and the third section 350 may move about the movable point 360 in either direction relative to the second section 330.

Although not shown, the reflector 40 may have three or more sections where at least one moveable point is disposed at the location of attachment for the reflector 40 to the mounting member 30, i.e. similar to FIG. 2 where the movable point 210 is disposed at the location of attachment between the reflector 40 and the mounting member 30.

The photovoltaic apparatus 300 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 of least one reflector 40. The reflector(s) 40 is/are configured to reflect light (represented by the arrows in the figure) onto the first side 12 and/or the second side 14 of the solar panel 10. The reflector(s) 40 may be fixed relative to the solar panel 10, such that the reflector(s) 40 and the solar panel 10 are configured to rotate together about an axis 50.

FIG. 4 depicts a side view of a photovoltaic apparatus 400 similar to the apparatuses described in FIGS. 1-3; similar numbers refer back to the same elements described therebefore. In addition, any additional features depicted in FIG. 4 may also be incorporated into any independent embodiment depicted in FIGS. 1-3 or incorporated into any combination of embodiments depicted in FIGS. 1-3.

FIG. 4 depicts a reflector 40 having at least two sections 420, 430 where a moveable point 210 separates a first section 420 from a second section 430. The first section 420 may move about the movable point 210 in either direction relative to the second section 430, and the second section 430 may move about the movable point in either direction relative to the first section 420.

The photovoltaic apparatus 400 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 of at least one reflector 40. The reflector(s) 40 is/are configured to reflect light (represented by the arrows in the figure) onto the first side 12 and/or the second side 14 of the solar panel 10. The reflector(s) 40 may be fixed relative to the solar panel 10, such that the reflector(s) 40 and the solar panel 10 are configured to rotate together about an axis 50.

FIG. 5 depicts a side view of a photovoltaic apparatus 500 similar to the apparatuses described in FIGS. 1-4; similar numbers refer back to the same elements described therebefore. Any additional features depicted in FIG. 5 may also be incorporated into any independent embodiment depicted in FIGS. 1-4 or incorporated into any combination of embodiments depicted in FIGS. 1-4.

FIG. 5 depicts a reflector 40 having at least two reflectors 40a, 40b attachable to a support arm 510. Said differently, the reflectors 40a, 40b have a space therebetween to allow for the placement of the support arm. The support arm 510 is configured to attach to the second location 34 of the mounting member 30. In a non-limiting embodiment, the support arm 510 may be another reflector, i.e. have reflective properties vis-à-vis the type of material of the support arm 510 and/or the coating and/or painting applied to the material of the support arm 510. The reflectors 40a, 40b may be attachable to the support arm 510 by any adhesive known to those skilled in the art (e.g. glue), or the reflectors 40a, 40b may be attachable to the support arm 510 by other known mechanisms, such as screwing the reflector(s) to the support arm, providing a jointed axis where the reflector(s) 40a, 40b may rotate about an axis relative to the support arm, and combinations thereof. Obviously, a first reflector 40a, 40b may be attachable to the support arm 510 by the same mechanism or a different mechanism from a second reflector 40a, 40b.

The reflectors 40a, 40b are depicted as having a curved/parabolic shape; however, the reflectors 40a, 40b may have any shape as long as the reflectors 40a, 40b are configured to reflect sunlight towards the first side and/or the second side of the solar panel 10.

The photovoltaic apparatus 500 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 the reflectors 40a, 40b. The reflectors 40a, 40b are configured to reflect light (represented by the arrows in the figure) onto the first side 12 and/or the second side 14 of the solar panel 10. The reflectors 40a, 40b may be fixed relative to the solar panel 10, such that the reflectors 40a, 40b and the solar panel 10 are configured to rotate together about an axis 50.

FIG. 6 depicts a side view of a photovoltaic apparatus 600 similar to the apparatuses described in FIGS. 1-5; similar numbers refer back to the same elements described therebefore. Any additional features depicted in FIG. 6 may also be incorporated into any independent embodiment depicted in FIGS. 1-5 or incorporated into any combination of embodiments depicted in FIGS. 1-5.

FIG. 6 depicts a reflector 40 having at least two reflectors 40a, 40b attachable to a support arm 510. The support arm 510 is configured to attach to the second location 34 of the mounting member 30. In a non-limiting embodiment, the support arm 510 may be another reflector, i.e. have reflective properties vis-à-vis the type of material of the support arm and/or the coating and/or painting applied to the material of the support arm 510. The reflectors 40a, 40b may be attachable to the support arm 510 by any adhesive known to those skilled in the art (e.g. glue), or the reflectors 40a, 40b may be attachable to the support arm 510 by other known mechanisms, such as screwing the reflector(s) to the support arm, providing a jointed axis where the reflector(s) 40a, 40b may rotate about an axis relative to the support arm, and combinations thereof. Obviously, a first reflector 40a, 40b may be attachable to the support arm 510 by the same mechanism or a different mechanism from a second reflector 40a, 40b. The reflectors 40a, 40b are depicted as having a flat shape; however, the reflectors 40a, 40b may have any shape as discussed in FIG. 5.

The photovoltaic apparatus 600 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 the reflectors 40a, 40b. The reflectors 40a, 40b are configured to reflect light (represented by the arrows in the figure) onto the first side 12 and/or the second side 14 of the solar panel 10. The reflectors 40a, 40b may be fixed relative to the solar panel 10, such that the reflectors 40a, 40b and the solar panel 10 are configured to rotate together about an axis 50.

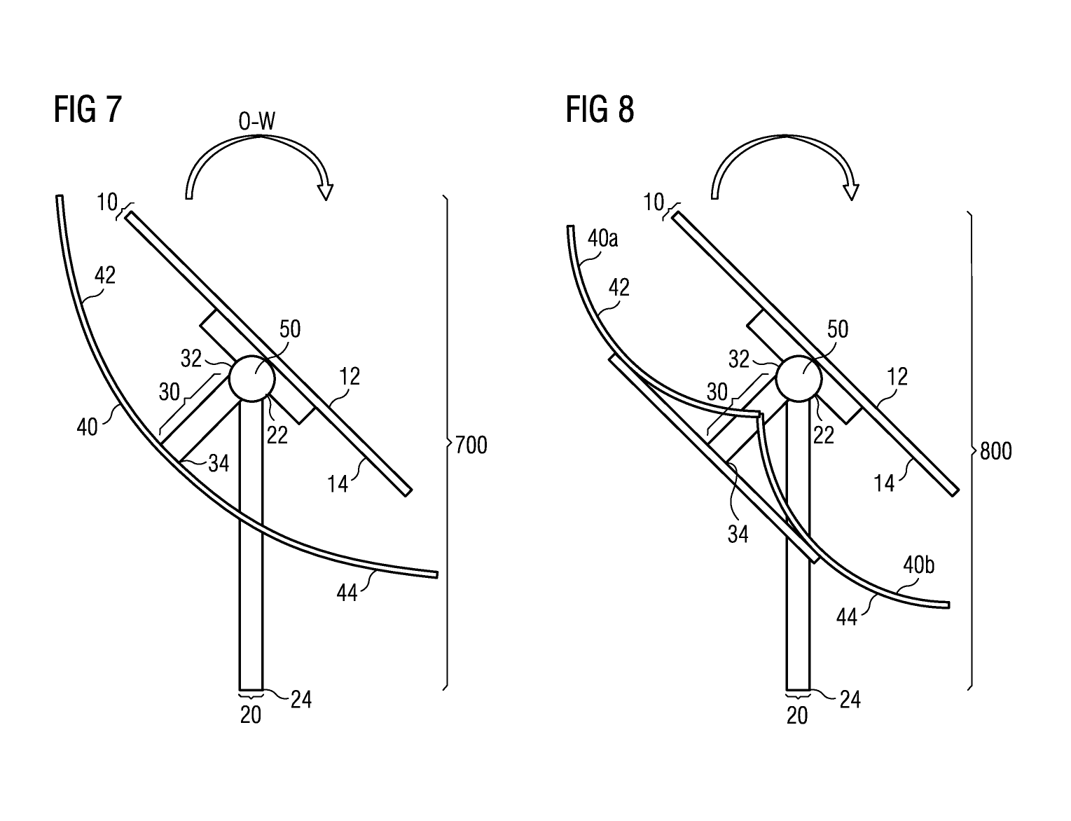

FIG. 7 depicts a side view of a photovoltaic apparatus 700 similar to the apparatuses described in FIGS. 1-6; similar numbers refer back to the same elements described therebefore. Any additional features depicted in FIG. 6 may also be incorporated into any independent embodiment depicted in FIGS. 1-6 or incorporated into any combination of embodiments depicted in FIGS. 1-6.

In various embodiments, a photovoltaic apparatus 700 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a first side 42 of least one reflector 40. The reflector(s) 40 is/are configured to reflect light (represented by the arrows in the figure) onto the first side 12 and/or the second side 14 of the solar panel 10. In addition, the reflector(s) 40 may be fixed relative to the solar panel 10, such that the reflector(s) 40 and the solar panel 10 are configured to rotate together about an axis 50. In a non-limiting embodiment, the reflector(s) 40 may have a parabolic shape.

FIG. 8 depicts a side view of a photovoltaic apparatus 800 similar to the apparatuses described in FIGS. 1-7; similar numbers refer back to the same elements described therebefore. Any additional features depicted in FIG. 8 may also be incorporated into any independent embodiment depicted in FIGS. 1-7 or incorporated into any combination of embodiments depicted in FIGS. 1-7.

FIG. 8 depicts a reflector 40 having at least two reflectors 40a, 40b attachable to a support arm 510 at a different first location than the first location described in previous non-limiting embodiments. The support arm 510 is configured to attach to the second location 34 of the mounting member 30. In a non-limiting embodiment, the support arm 510 may be another reflector, i.e. have reflective properties vis-à-vis the type of material of the support arm and/or the coating and/or painting applied to the material of the support arm 510. The reflectors 40a, 40b may be attachable to the support arm 510 and/or the mounting member 30 by any adhesive known to those skilled in the art (e.g. glue), or the reflectors 40a, 40b may be attachable to the support arm 510 by other known mechanisms, such as screwing the reflector(s) to the support arm and/or the mounting member 30, and combinations thereof. Obviously, a first reflector 40a, 40b may be attachable to the support arm 510 and/or the mounting member 30 by the same mechanism or a different mechanism from a second reflector 40a, 40b. The reflectors 40a, 40b are depicted as having a curved/parabolic shape; however, the reflectors 40a, 40b may have any shape as long as the reflectors 40a, 40b are configured to reflect sunlight towards the first side 12 and/or the second side 14 of the solar panel 10.

The photovoltaic apparatus 800 may include a solar panel 10 having a first side 12 and a second side 14 where the solar panel 10 includes at least one bifacial cell (not shown). The second side 14 of the solar panel 10 may be rotatably attached to a first location 22 of a support structure 20; a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to a support arm 510. The reflectors 40a, 40b are configured to reflect light (represented by the arrows in the figure) onto the first side 12 and/or the second side 14 of the solar panel 10. The reflectors 40a, 40b may be fixed relative to the solar panel 10, such that the reflectors 40a, 40b and the solar panel 10 are configured to rotate together about an axis 50.

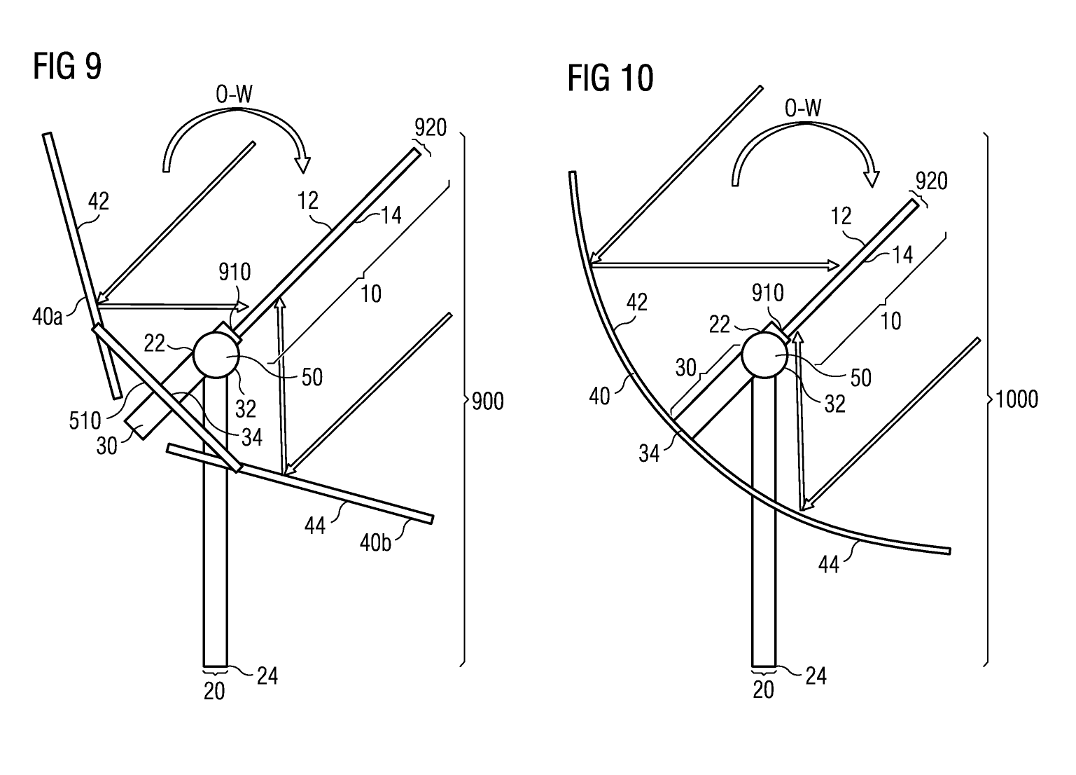

FIG. 9 depicts a side view of a photovoltaic apparatus 900 similar to the apparatuses described in FIGS. 1-8; similar numbers refer back to the same elements described therebefore. Any additional features depicted in FIG. 9 may also be incorporated into any independent embodiment depicted in FIGS. 1-8 or incorporated into any combination of embodiments depicted in FIGS. 1-8.

FIG. 9 depicts at least one reflector 40 having at least two reflectors 40a, 40b attachable to a support arm 510. The support arm 510 is configured to attach to the second location 34 of the mounting member 30. Here, the second location 34 of the mounting member 30 is a different location from the second location described in previous figures; ‘second location’ is used herein to refer to a location of the mounting member different from the ‘first location’, and ‘second location’ may be any location along the mounting member that is different from the ‘first location’. Said differently, the support arm 510 and/or the reflector(s) 40 of any previous FIGS. 1-8 may be attachable to the mounting member anywhere along the mounting member at a ‘second location’.

In addition, the solar panel 10 may have a first side 12 and a second side 14 where sun energy may be reflected thereonto from the solar reflector(s) 40. The solar panel may also have a first end 910 and a second end 920; the first end 910 of the solar panel 10 may be rotatably attachable to the first location 22 of the support structure 20.

In a non-limiting embodiment, the support arm 510 may be another reflector, i.e. have reflective properties vis-à-vis the type of material of the support arm and/or the coating and/or painting applied to the material of the support arm 510. The reflectors 40a, 40b may be attachable to the support arm 510 by any adhesive known to those skilled in the art (e.g. glue), or the reflectors 40a, 40b may be attachable to the support arm 510 by other known mechanisms, such as screwing the reflector(s) to the support arm, providing a jointed axis where the reflector(s) 40a, 40b may rotate about an axis relative to the support arm, and combinations thereof. Obviously, a first reflector 40a, 40b may be attachable to the support arm 510 by the same mechanism or a different mechanism from a second reflector 40a, 40b. The reflectors 40a, 40b are depicted as having a flat shape; however, the reflectors 40a, 40b may have any shape as discussed in FIG. 5.

The solar panel 10 includes at least one bifacial cell (not shown), and a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to the support arm 510. The reflectors 40a, 40b may be configured to reflect light (represented by the arrows in the figure) onto the first side 12 and/or the second side 14 of the solar panel 10. The support arm 510 may be fixed relative to the solar panel 10, such that the support arm 510, the reflectors 40a, 40b, and the solar panel 10 are configured to rotate together about an axis 50.

FIG. 10 depicts a side view of a photovoltaic apparatus 1000 similar to the apparatuses described in FIGS. 1-9; similar numbers refer back to the same elements described therebefore. Any additional features depicted in FIG. 10 may also be incorporated into any independent embodiment depicted in FIGS. 1-9 or incorporated into any combination of embodiments depicted in FIGS. 1-9.

In various embodiments, a photovoltaic apparatus 1000 may include a solar panel 10 having a first side 12 and a second side 14 where sun energy may be reflected thereonto from the solar reflector(s) 40. The solar panel 10 may also have a first end 910 and a second end 920; the first end 910 of the solar panel 10 may be rotatably attachable to the first location 22 of the support structure 20.

The solar panel 10 may include at least one bifacial cell (not shown), and a second location 24 of the support structure 20 may be configured to attach to a ground surface (not shown). The first location 22 of the support structure 20 may also be configured to rotatably attach to a first location 32 of a mounting member 30. A second location 34 of the mounting member 30 may be configured to rotatably attach to at least one reflector 40. The reflector(s) 40 is/are configured to reflect light (represented by the arrows in the figure) onto the first side 12 and/or the second side 14 of the solar panel 10. In addition, the reflector(s) 40 may be fixed relative to the solar panel 10, such that the reflector(s) 40 and the solar panel 10 are configured to rotate together about an axis 50. In a non-limiting embodiment, the reflector(s) 40 may have a parabolic shape.

The bifacial solar cells may be silicon solar cells such as but not limited to a crystalline silicon solar cell, or a single-crystalline silicon solar cell, or a poly-crystalline silicon solar cell, or a nano-crystalline silicon solar cell, or an amorphous silicon solar cell, or a quasi-mono-crystalline silicon solar cell, or combinations thereof.

In various embodiments, the bifacial solar cell may have a front side and a rear side where both the front side and the rear side may be configured to capture solar energy, i.e. receive light. A bifacial solar cell is to be understood as a solar cell, which has a grid of contact fingers (e.g. made of aluminum) on the front side and the rear side of the bifacial solar cell.

The contacts may be formed on a solar cell substrate and serve to collect electrical charge carriers generated within the solar cell substrate. The solar cell substrate may include an optically active region.

The contacts may be formed directly on the surfaces of the solar cell substrate. By way of example, the contacts may be configured as a metallization. The contacts may be patterned over the optically active region, e.g. as so-called contact fingers as a metallization or e.g. as a selective emitter or as a combination thereof. A patterned metallization may e.g. be formed substantially only over or on the optically active region (except for electric cross lines).

The optically active region of the bifacial solar cell may include an electrically conductive and/or semiconductive material, e.g. a doped silicon, e.g. p doped (p type), e.g. doped with dopants of boron, gallium and/or indium, or n doped (n type), e.g. doped with dopants of phosphorous, arsenic and/or antimon.

The optically active region may absorb electromagnetic radiation and may generate photo current from this. The electromagnetic radiation may have a wavelength range which includes UV radiation (A to C), visible light and/or infrared radiation (A to C).

The optically active region may include a first region doped with a dopant of a different doping type as a second region in a non-limiting embodiment. The first region may be in physical contact with the second region and share a common interface. By way of example, the first region may be a p type (doped with p dopant(s)) and the second region may be an n type (doped with n dopant(s)), and vice versa. A pn junction may be formed at the interface between the first region and the second region. Positive charge carriers (e.g. holes) and negative charge carriers (e.g. electrons) may be separated in the pn junction. The optically active region may include a plurality of pn junctions, which may be arranged next to each other or one above the other.

The contact structure may optionally include a dielectric layer structure and at least one or more solder pad regions. The dielectric layer structure may include one or more dielectric layers. A plurality of local contact openings partially exposing a front side and/or rear side of the solar cell substrate may be formed through the dielectric layer structure.

Dielectric material, e.g. dielectric material of the dielectric layer structure may be laterally disposed between the solder pad regions. In various embodiments, each solder pad region may have a covered surface area greater than 10 mm². The distance between two solder pad regions may range from about 2 mm to about 20 mm, e.g. range from about 5 mm to about 15 mm, e.g. in the range from about 7 mm to about 12 mm. A plurality of (i.e. at least two) partial solder pads may be arranged in each solder pad region in a non-limiting embodiment. As will be described in more detail below, the solder pads may in general have any desired shape. Furthermore, the partial solder pads may be separated, e.g. laterally electrically insulated from each other within each of the solder pad regions. Dielectric material may be arranged laterally between the partial solder pads within each of the solder pad regions. As an alternative, semiconducting material, such as e.g. silicon, may be arranged laterally between the partial solder pads within each of the solder pad regions. The partial solder pads may include or essentially consist of a metal (in the following also referred to as a first metal), e.g. silver and/or nickel. In various embodiments, the smallest distance between two respective partial solder pads in a respective solder pad region may be in the range from about 0.1 mm to about 1.0 mm, e.g. in the range from about 0.3 mm to about 0.8 mm, e.g. in the range from about 0.5 mm to about 0.6 mm. As will be described in more detail below, at least two rows of partial solder pads may be formed in each solder pad region. Furthermore, at least four partial solder pads may be formed in each solder pad region.

The local contact openings may be formed as trenches (having any desired cross section and having any desired shape), e.g. by means of one or more laser beams, which e.g. may be generated by means of one or more lasers. The extension of the local contact openings may be limited by corresponding controlling of the laser beam(s). As an alternative, the extension of the local contact openings may be limited by means of a shadow mask. As an alternative, the local contact openings may be etched. It is to be noted that the local contact openings may be formed in any desired form, e.g. as trenches.

In various embodiments, the dielectric layer structure (which may also be referred to as passivation layer) may include a first dielectric layer, wherein the first dielectric layer may be formed, e.g. deposited, on or over the optically active region at the front side and/or rear side of the solar cell substrate. Furthermore, the dielectric layer structure may include a second dielectric layer. The second dielectric layer may be formed, e.g. deposited, on or over the first dielectric layer.

The first dielectric layer may include or essentially consist of the same material as the second dielectric layer. The first dielectric layer may include silicon nitride (e.g. Si₃N₄), silicon oxide (e.g. SiO₂) and/or silicon oxynitride (SiON), alternatively e.g. aluminum oxide (e.g. Al₂O₃). The first dielectric layer may have a lower refractive index than the second dielectric layer (at the same wavelength). In general, the dielectric layer structure may include or essentially consist of any material which is suitable for a passivation of the of the solar cell substrate, with which the material of the metallization (e.g. aluminum) cannot form an alloy, as will be described in more detail below. In various embodiments, the dielectric layer structure may have a layer thickness in the range from about 10 nm to about 500 nm, e.g. in the range from about 20 nm to about 250 nm.

Furthermore, a metallization may be formed at the front side and/or the rear side of the substrate, which may partly overlap the solder pad region, the solder pads, or the partial solder pad. The metallization may include a second metal different from the first metal. The metallization may include or essentially consist of e.g. aluminum. The metallization may also be partially formed in the local contact openings and may form a physical contact and thus a common interface with the first metal (e.g. silver or nickel) of the solder pads. Thus, a plurality of local contacts may be formed in each of the solder pad regions. In other words, a plurality of vertical current paths (each formed by a respective partial solder pad) may be provided in each of the solder pad regions (from the solar cell substrate to the metallization), which are laterally separated from each other. The second metal may be formed on or over the first metal in the local contact openings.

Furthermore, in various embodiments, plane openings may be provided in the metallization, which may include or essentially consist of a well solderable metallization (also referred to as further metallization), such as e.g. silver, nickel, and/or tin. The further metallization may be arranged over non-opened portions of the dielectric layer structure.

The contact structure may be configured to collect the light induced charge carriers, which are discharged from the local contact openings from the optically active region of the solar cell substrate. In other words, the dielectric layer structure may include one or more electrically conductive regions, which are configured to electrically connect the optically active region, e.g. as through contacts or intermediate connections. The through contacts may be formed as electrically conductive regions in the dielectric layer structure (in other words in the passivation layer) such that a continuous electrically conducting connection is formed through the entire dielectric layer structure.

In various embodiments, at least one bifacial solar cell, as described above, may be provided in the solar panel. The plurality of bifacial solar cells may be electrically connected with each other in series and/or in parallel.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photovoltaic apparatus comprising:
a solar panel having at least one bifacial solar cell; wherein the solar panel comprises a first side and a second side;
a mounting member comprising a first location and a second location; wherein the first location of the mounting member is configured to attach to the first location of the support structure;
a support structure comprising a first location and a second location; wherein the first location of the support structure is configured to rotatably attach to the first location of the mounting member; and wherein the second location of the support structure is configured to attach to a ground surface;
at least one reflector configured to attach to the second location of the mounting member; wherein the at least one reflector reflects light onto the second side of the solar panel; and wherein the at least one reflector is fixed relative to the solar panel; and wherein the at least one reflector and the solar panel are configured to rotate together about an axis.

2. The apparatus of claim 1, wherein the at least one reflector comprises at least two sections where a first section is configured to face in a different direction from at least one other section.

3. The apparatus of claim 2, wherein the at least one reflector is configured to rotate about its own axis.

4. The apparatus of claim 1, wherein the at least one reflector comprises a curved shape.

5. The apparatus of claim 1, wherein the at least one reflector is arranged substantially parallel to the solar panel.

6. The apparatus of claim 1, wherein the at least one reflector is configured to rotate about a first axis, and the solar panel is configured to rotate about a second axis.

7. The apparatus of claim 1, wherein the at least one reflector has at least two sections; wherein a first section is configured to attach to at least one other section at a rotatable point.

8. The apparatus of claim 1, wherein the at least one reflector comprises a support arm, and wherein the support arm is configured to attach to the second location of the mounting member.

9. The apparatus of claim 1, wherein the at least one reflector, the mounting member, and the solar panel are weight balanced at an axis point.

10. The apparatus of claim 1, wherein the at least one reflector comprises a material selected from the group consisting of a metal, a plastic or rubber, or combinations thereof comprising a surface albedo of greater than 50%.

11. The apparatus of claim 1, wherein the at least one reflector comprises a material selected from the group consisting of a coated material, a painted material, a ridged material, a perforated material, a corrugated material, and combinations thereof.

12. The apparatus of claim 1, wherein at least one dimension of the at least one reflector extends beyond at least one dimension of the solar panel.

13. The apparatus of claim 1, wherein the at least one reflector comprises at least two reflectors, and wherein the at least two reflectors have a space therebetween.

14. A photovoltaic apparatus comprising:
a solar panel having at least one bifacial solar cell; wherein the solar panel comprises a first side, a second side;
a mounting member comprising a first location and a second location; wherein the first location of the mounting member is configured to rotatably attach to the first location of the support structure;
a support structure comprising a first location and a second location; wherein the first location of the support structure is configured to rotatably attach to the mounting member; and wherein the second location of the support structure is configured to attach to a ground surface;
at least two reflectors configured to attach to the second location of the mounting member; wherein a first reflector reflects light onto the first side and a second reflector reflects light onto the second side of the solar panel; and wherein the at least two reflectors are fixed relative to the solar panel; and wherein the at least two reflectors and the solar panel are configured to rotate together about an axis.

15. The apparatus of claim 14, wherein the at least two reflectors, the mounting member, and the solar panel are weight balanced at an axis point.

16. The apparatus of claim 14, wherein the surface of the at least two reflectors comprise a surface albedo of 80% or more.

17. The apparatus of claim 14, wherein the at least two reflectors are arranged within an angle of about 45 degrees relative to the solar panel.

18. The apparatus of claim 14, wherein one the at least two reflectors comprises a curved shape.
